(19) United States
(12) Patent Application Publication
(10) Pub. No.: US 2009/0114970 A1
(43) Pub. Date: May 7, 2009

(54) EMBEDDED DRAM WITH INCREASED CAPACITANCE AND METHOD OF MANUFACTURING SAME

(75) Inventors: Veronique De-Jonghe, La Terrasse (FR); Audrey Berthelot, Saint Ismier (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/816,706

(22) PCT Filed: Feb. 15, 2006
(86) PCT No.: PCT/IB06/50493

§ 371 Date: Dec. 30, 2008

(30) Foreign Application Priority Data
Feb. 18, 2005 (EP) 05300129.3

(51) Int. Cl. H01L 27/06; H01L 21/71

(52) U.S. Cl. 257/306; 438/396; 257/532; 257/E21.536; 257/E27.024

(57) ABSTRACT

An embedded DRAM memory device comprising one or more cylinder type cell capacitors. Contact pillars (25) are provided in a PMD layer (27) on a substrate (10), and the lower (or storage mode) electrodes of the capacitors are formed by depositing an end stop layer (40) over the contact pillars (25) and then forming second contact trenches (62) in an oxide layer (60) provided over the PMD layer (27). The second contact trenches (62) are aligned with respective contact pillars (25) and filled with, for example, a barrier material plus tungsten. The oxide layer (60) is selectively etched at the location of the contact trench (62) to the end stop layer (40). The end stop layer etched and the PMD layer (27) is subsequently etched along a portion of the length of the first contact pillar (25) to form a trench (62). Finally, the tungsten in the second contact trench (62) is selectively etched through the barrier layer, so as to leave a barrier layer (64) e.g of TiN, on the inner walls and floor of the second trench (62).

### FIELD OF THE INVENTION

The invention relates to an embedded dynamic random access memory (DRAM) with increased capacitance and, more particularly to a method of forming a high performance capacitor for use in such a device.

### BACKGROUND OF THE INVENTION

Several trends exist presently in the semiconductor fabrication and electronics industries, whereby efforts are directed toward the continual minimization of the size and power consumption of devices. One reason for such trends is that more portable devices are being fabricated which are relatively small and portable, and therefore tend to rely on a relatively small battery as their primary power source. For example, cellular telephones, personal computing devices and personal sound systems are among devices which are in increasing demand in the consumer market. In addition to the continual decrease in size and increase in portability, personal devices like these are required to have increasingly more computational power and on-chip memory. In light of these demands, there is a need to provide a memory device which has memory and logic functions integrated onto the same semiconductor chip, and integrating DRAM (dynamic random access memory) with logical functions enables rapid access to the information contained thereon.

A basic DRAM cell is composed of a capacitor to store information and a transistor acting as an on/off switch. Several types of DRAM memory cells are in common use, including a single capacitor and a dual capacitor memory cell. The one transistor-one capacitor memory cell type requires less silicon area than the dual capacitor type, but is less immune to noise and process variations. In addition, this type of single capacitor cell type requires a voltage reference for determining a stored memory state. On the other hand, the dual capacitor memory cell requires more silicon area, but stores complementary signals allowing differential sampling of the stored information. In addition, the dual capacitor memory cell is typically more stable than the single capacitor memory cell.

Thus, one of the more important parameters of a DRAM cell is its capacitance:

C=(∈ᵣ·∈₀·S)/d

where:
∈ᵣ is the relative permittivity of the dielectric
∈₀ is the vacuum permittivity
d is the distance between the two electrodes
S is the surface of the electrodes

As memory cell density increases, there is a continuing challenge to maintain sufficiently high storage capacitance despite decreasing cell area. One way of increasing cell capacitance is by the use of three-dimensional cell capacitor structures, such as trenched or stacked capacitors.

Memory devices such as DRAM devices require a high performance capacitor with sufficient capacitance in order to increase both its refresh period and its tolerance to alpha particles. However, to implement this high performance cell capacitor, it is necessary to either increase the area between an upper electrode (plate electrode) and a lower electrode (storage node electrode) that overlaps, or reduce the thickness of a dielectric film interposed between the upper and lower electrodes. The latter option requires that the dielectric film between the electrodes be made of a material having a high dielectric constant (HiK).

Thus, three-dimensional structures, as well the use of HiK dielectrics enable the capacitance of a DRAM cell to be increased. However, this parameter becomes increasingly critical and difficult to optimize as technological generations progress.

Referring to FIG. 1 of the drawings, a conventional DRAM device including a cylinder type cell capacitor comprises a semiconductor substrate 10 having active regions comprising a source or a drain 20 covered by an electrode 21. The extensions of the active regions are covered by spacers 24 surrounding a gate 22 covered by a gate electrode 23. An insulating layer 30 is also provided over the electrodes 21 and 23 and the spacers 24, over which is provided a first insulating layer 27, e.g. a pre-metal dielectric layer, hereinafter referred to as PMD1 layer. The PMD1 layer 27 is patterned, using a photolithography technique and an etching technique, to form node contact holes or trenches which expose the active regions through the insulating layer 30 and the trenches are filled with conductive material to form contact pillars 25.

Next, an etch stop layer 40 is deposited over the contact pillar structure 25 and the PMD1 layer. Then, a second insulating layer 60, hereinafter referred to as PMD2 layer is provided over the etch stop layer 40. The PMD2 layer is patterned to form capacitor holes exposing predetermined portions of the etch stop layer 40 and the exposed portions of the etch stop layer 40 are then dry-etched to expose the top surfaces of the contact plugs 25. A conductive material such as poly-silicon is provided in the capacitor hole: this is the lower electrode 50 of the capacitor. It is followed by dielectric and second electrode deposition (not shown).

One of the known possibilities for increasing capacitance is to increase the height of the cylinder (i.e. the lower or storage node electrode 50) creating the capacitance. By this method, the surface area of the storage node electrode is increased so as to increase the capacitance of the capacitor.

However, this is soon limited by constraints on the High Aspect Ratio contact etching, in the sense that an aspect ratio that is too high for the embedded DRAM-contact can lead to etch stop.

US Patent Application Publication No. US 2004/0159909 A1 describes a method of forming a high performance capacitor using an isotropic etching process to optimize the surface area of the lower electrodes. Multiple sacrificial oxide layers are provided on an etch stop layer covering an insulating layer with contact plugs. The multiple sacrificial layers are patterned and additionally isotropically etched to form an expanded capacitor hole. An exposed portion of the etch stop layer is then etched to form a final capacitor hole exposing an upper portion of a respective contact plug and a portion of the insulating layer adjacent thereto. A conformal conductive layer is then formed on the semiconductor substrate and selectively removed from the upper surface of the upper sacrificial oxide layer to form cylinder type lower electrodes.

However, this method requires a relatively large number of masking steps, which increases the cost and complexity of the fabrication process.

### SUMMARY OF THE INVENTION

It is therefore an object of the present invention to provide a method of fabricating a high performance capacitor, in which the number of masking steps is minimized whilst maintaining the aspect ratio for the contact etching processes at an acceptably low level.

In accordance with the present invention, there is provided a method of forming a capacitor on a substrate, said capacitor comprising first and second electrodes with a dielectric material therebetween, the method comprising forming a conductive contact pillar in a first layer of material provided on said substrate, forming said first electrode by forming a plug of conductive material within a capacitor hole, provided in a second layer of material provided over said first layer of material, said capacitor hole being aligned with said conductive contact pillar, selectively etching a trench in said second layer of material long the side walls of said capacitor hole and extending said trench through said first layer of material along at least a portion of the side walls of said conductive contact pillar, and partially etching said plug of conductive material so as to leave a barrier layer on the side walls of said capacitor hole.

In simpler terms, the method consists of forming a capacitor comprising first and second electrodes and a dielectric material therebetween, the method comprising forming two concentric cylinders in order to increase surface area of electrodes. The first cylinder is a plug of conductive material which will be particularly emptied to keep only the barrier (e.g. TIN) on the side walls of plug which will play the role of mechanical support for electrodes deposition. The second cylinder is a hole aligned with the first cylinder (contact pillar). It is formed by a trench selectively etched in the second layer of material along the side walls of the first cylinder and partially etched in the first layer of material (e.g. the PMD1 layer referred to above).

As a result, and without increasing the number of masking steps or the aspect ratio, the surface area of the first (or lower) electrode of the capacitor and, therefore, the capacitance of the structure, can be significantly increased relative to the prior art.

Also in accordance with the present invention, there is provided a capacitor formed on a substrate, said capacitor comprising first and second electrodes with a dielectric material therebetween, wherein a conductive contact pillar is provided in a first layer of material on said substrate, said first electrode is provided in a second layer of material provided over said first layer of material, said first electrode being aligned with said conductive contact pillar and comprising a capacitor hole having a layer of conductive material provided on the inner walls thereof, wherein a trench is provided in said second layer of material along the side walls of said first electrode and along at least a portion of the side walls of said conductive contact pillar.

Preferably, an end stop layer (ESL) formed, for example, of SiN or similar material, is provided between said first and second layers of material. The first layer of material may, for example, comprise a pre-metal dielectric (PMD) layer formed over the substrate prior to formation of said conductive contact pillar. An insulating layer is beneficially provided between the substrate and the first layer of material.

The plug of conductive material may, for example, comprise tungsten. The second layer of material beneficially comprises an oxide material. In a preferred embodiment of the method, the second layer of material is deposited over the first layer of material in two separate steps, wherein a first portion of the second layer of material is first deposited over the first layer of material, in which portion is formed said capacitor hole, then said capacitor hole is provided with said plug of conductive material, following which the remaining portion of said second layer of material is deposited over said first portion. Beneficially, a barrier layer is deposited over said first portion prior to deposition of said remaining portion of said second layer of material.

The present invention extends to a DRAM memory cell comprising one or more capacitors as defined above and one or more transistors for selectively switching said one or more capacitors on and off, and to an integrated circuit comprising one or more of said DRAM memory cells thereon.

These and other aspects of the present invention will be apparent from, and elucidated with reference to, the embodiment described herein.

### BRIEF DESCRIPTION OF THE DRAWINGS

An embodiment of the present invention will now be described by way of example only and with reference to the accompanying drawings, in which:

FIG. 1 is a schematic cross-sectional view of a DRAM cell in accordance with the prior art; and

FIG. 2 is a schematic cross-sectional view of a DRAM cell in accordance with an exemplary embodiment of the present invention.

### DETAILED DESCRIPTION OF THE INVENTION

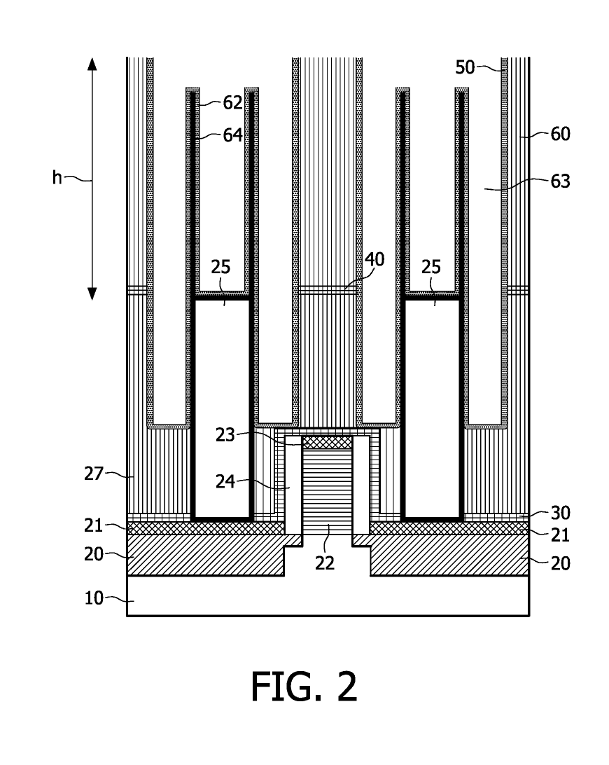

Referring to FIG. 2 of the drawings, a DRAM device including a cylinder type cell capacitor according to an exemplary embodiment of the present invention comprises a semiconductor substrate 10 having active regions comprising a source or a drain 20 covered by an electrode 21. The extensions of the active regions are covered by spacers 24 surrounding a gate 22 covered by a gate electrode 23. An insulating layer 30 is also provided over the electrodes 21 and 23 and the spacers 24, over which is provided a first insulating layer 27, e.g. a pre-metal dielectric layer, hereinafter referred to as PMD1 layer. The PMD1 layer 27 is patterned, using a photolithography technique and an etching technique, to form node contact holes or trenches which expose the active regions through the insulating layer 30 and the trenches are filled with conductive material to form contact pillars 25.

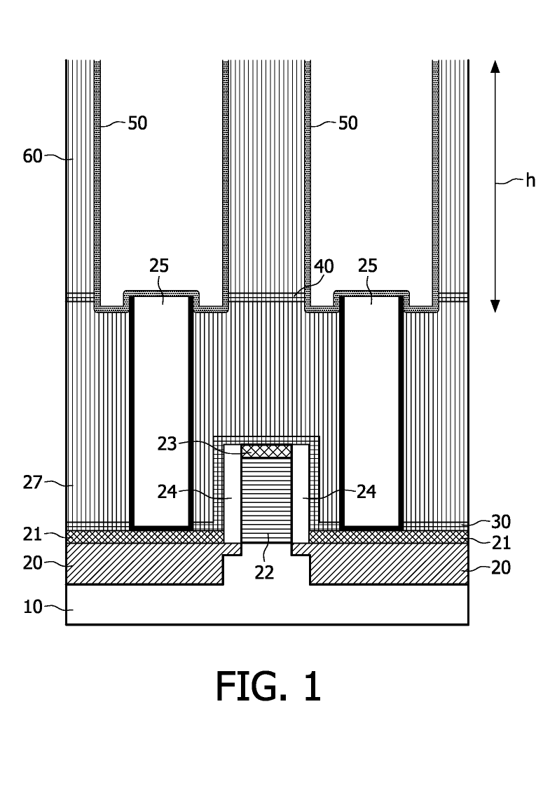

Next, an End Stop Layer (ESL) 40 is deposited over the contact pillars 25 and the PMD1 layer. Then, a first portion of a second insulating layer 60, hereinafter referred to as PMD2 layer, (e.g. 80% of the thickness of the PMD2 layer used in the conventional device described with reference to FIG. 1) is deposited over the ESL layer 40. Next, a second contact trench 62 is formed by means of photolithography or etching, and a barrier layer (not shown) is formed which may, for example, comprise TiN or another material having similar properties. The second contact trench 62 is then filled with a conductive material such as tungsten (W), which is subjected to a CMP process, following which a second portion of the PMD2 layer, of a thickness say the remaining 20% of the PMD2 layer of the conventional device, is deposited over the first portion of the PMD2 layer. The second PMD2 layer is then selectively etched at the location of the contact trench 62 and the first oxide layer 60 is etched to the end stop layer 40. The end stop layer (ESL) 40, which may be formed of SiN, for example, is then etched and the PMD1 layer 27 is then etched along a portion of the length of the first contact pillar 25 to form an elongate trench 63.

Finally, the tungsten in the second contact trench 62 is selectively etched through the barrier layer, so as to leave a layer (such as TiN) 64 on the inner walls and floor of the second trench 62. The barrier layer left plays the role of mechanical support for the electrode deposition process during which a conductive material such as poly-silicon is provided in the capacitor hole, forming the lower electrode 50 of the capacitor.

As stated above, the capacitance of the resultant structure is directly proportional to the surface area S of the electrodes. In the prior art structure, S=s+h*p, where s is the surface area of the bottom of the electrode, h is the height of the electrode and p is the perimeter of the electrode.

In the structure illustrated in FIG. 2 of the drawings, and described above with reference thereto, S=s+(h+2*0.5*h+2*0.8*h)*p=s+3.6*h*p.

Thus, without changing the aspect ratio (i.e. without changing h) and without any additional masking steps (only one additional contact lithography step), the above-described embodiment of the present invention enables the surface area of the electrode to be significantly increased, and it is thought that it should be possible to at least double the capacitance of the resultant structures.

Since the additional contact barrier is not affected by the etching process, it allows an increase in the capacitor surface area relative to the prior art structures. In the special case of a MIM (Metal-Insulator-Metal) capacitor, it is proposed to use electrodes comprising two concentric cylinders with a dielectric deposited as an ALD (atomic layer deposit) in order to follow the surface of the structure and maximize the surface area gain.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. A method of forming a capacitor on a substrate, said capacitor comprising first and second electrodes with a dielectric material therebetween, the method comprising:
forming a conductive contact pillar in a first layer of material provided on said substrate,
forming said first electrode by forming a plug of conductive material within a capacitor hole, provided in a second layer of material provided over said first layer of material, said capacitor hole being aligned with said conductive contact pillar,
selectively etching a trench in said second layer of material long the side walls of said capacitor hole and extending said trench through said first layer of material along at least a portion of the side walls of said conductive contact pillar, and
partially etching said plug of conductive material so as to leave a layer thereof on the side walls of said capacitor hole.

2. A method according to claim 1, wherein an end stop or dielectric layer is provided between said first and second layers of material.

3. A method according to claim 1, wherein the first layer of material comprises a pre-metal dielectric layer formed over the substrate in prior to formation of said conductive contact pillar.

4. A method according to claim 1, wherein an insulating layer is provided between the substrate and the first layer of material.

5. A method according to claim 1, wherein said plug of conductive material comprises tungsten.

6. A method according to claim 1, wherein said second layer of material comprises an oxide material.

7. A method according to claim 1, wherein the second layer of material is deposited over the first layer of material in two separate steps, wherein a first portion of the second layer of material is first deposited over the first layer of material, in which portion is formed said capacitor hole, then said capacitor hole is provided with said plug of conductive material, following which the remaining portion of said second layer of material is deposited over said first portion.

8. A method according to claim 7, wherein a barrier layer is deposited over said first portion prior to deposition of said remaining portion of said second layer of material.

9. A capacitor formed on a substrate, said capacitor comprising first and second electrodes with a dielectric material therebetween, wherein a conductive contact pillar is provided in a first layer of material on said substrate, said first electrode is provided in a second layer of material provided over said first layer of material, said first electrode being aligned with said conductive contact pillar and comprising a capacitor hole having a layer of conductive material provided on the inner walls thereof, wherein a trench is provided in said second layer of material along the side walls of said first electrode and along at least a portion of the side walls of said conductive contact pillar.

10. A DRAM memory cell comprising one or more capacitors according to claim 9 and one or more transistors for selectively switching said one or more capacitors on and off.

11. An integrated circuit including one or more DRAM memory cells according to claim 10.
